(19) United States
(12) Patent Application Publication
(10) Pub. No.: US 2026/0218028 A1
(43) Pub. Date: Jul. 30, 2026

(54) SHEET FORM HEAT-DISSIPATING MEMBER

(71) Applicant: SHIN-ETSU CHEMICAL CO., LTD., Tokyo (JP)

(72) Inventor: Yuya HIRONAKA, Annaka-shi (JP)

(73) Assignee: SHIN-ETSU CHEMICAL CO., LTD., Tokyo (JP)

(21) Appl. No.: 19/146,288

(22) PCT Filed: Dec. 1, 2023
(86) PCT No.: PCT/JP2023/043182

§ 371 Date: Jul. 8, 2025

(30) Foreign Application Priority Data
Jan. 16, 2023 (JP) 2023-004371

(51) Int. Cl. C09K 5/06; C08G 77/00; C08G 77/04; C08G 77/12; C08G 77/20; C08K 5/5425; C08K 7/18; C08K 13/04; C09K 5/14

(52) U.S. Cl. CPC C09K 5/063; C08G 77/045; C08G 77/12; C08G 77/20; C08K 5/5425; C08K 7/18; C08K 13/04; C09K 5/14; C08G 77/80; C08K 2201/001; C08K 2201/014

(57) ABSTRACT

A sheet form heat-dissipating member to be provided between a heat-generating electronic component and a heat-dissipating component, wherein the sheet form heat-dissipating member contains a heat-softening thermally conductive composition including: (A) 100 parts by mass of a silicone resin having a melting point of 110° C. or less, (B) 500 to 1,850 parts by mass of silver powder, and (C) 1.0 to 20 parts by mass of an organohydrogenpolysiloxane, the silver powder as component (B) has an average particle diameter of 0.5 to 10 μm, and the heat-softening thermally conductive composition includes 30 to 60 vol % of the silver powder as component (B), and the organohydrogenpolysiloxane as component (C) includes an organohydrogenpolysiloxane having two or more hydrosilyl groups in one molecule. Thus, the present invention can provide a sheet form heat-dissipating member that exhibits thermal conductivity even under heat compression at approximately 150° C. and that has excellent heat dissipation performance.

### TECHNICAL FIELD

The present invention relates to a sheet form heat-dissipating member.

### BACKGROUND ART

In electronic devices, heat-dissipating components (cooling components) such as heat sinks are installed to dissipate heat generated from heat-generating components such as semiconductor devices. A heat-dissipating member is used by being sandwiched between the heat-generating component and the heat-dissipating component to efficiency transfer heat to the heat-dissipating component. The heat-dissipating member includes a thermally conductive sheet, a heat-conductive grease, a curable heat-conductive grease, and the like, and is used appropriately according to the application.

Generally, the thermally conductive sheet is superior to the heat-conductive grease in workability when assembling the heat radiator. However, it is difficult to reduce the thickness of the thermally conductive sheet, and it cannot follow minute unevenness on the surfaces of electronic components and the heat sinks. Therefore, there is a problem that the contact thermal resistance becomes large and heat cannot be efficiently conducted.

Within this context, a thermally conductive sheet that softens upon heating has been proposed. The thermally conductive sheet using low melting point metal such as metallic indium has significantly low thermal resistance due to melting of metal by heating (Patent Document 1). However, since molten metal has a low viscosity, it is possible that metal will flow out when reheated to a temperature above the melting point.

In silicone-based phase change sheets, which can maintain viscosity even when heated, the silicone becomes softer when heated and provides lower thermal resistance. However, resin-based thermally conductive sheets such as silicone, and the like, have lower thermal conductivity than metallic indium, and the like, (Patent Document 2).

Silver fillers are attracting attention to improve thermal conductivity of resin-based heat dissipating materials. Silver has very high thermal conductivity as a single substance, and can form a thermal conduction path efficiently by partially sintering fillers during heating. Therefore, the heat dissipating material with silver filler can be expected to significantly improve the thermal performance. However, since the sintering temperature of silver filler is high at 200° C. or more, it is difficult to incorporate such a high-temperature bonding process into the assembly process.

Nano-sized silver (nanosilver) has been proposed as a low-temperature sintering technique for silver fillers (Patent Document 3). However, due to the high cost of nanosilver and the difficulty in achieving uniform dispersion within the composition, stable mass production and commercialization of the composition containing nanosilver is challenging.

### CITATION LIST

### Patent Literature

Patent Document 1: JP 2021-169582 A
Patent Document 2: JP 2019-182980 A
Patent Document 3: JP 2017-95642 A

### SUMMARY OF INVENTION

### Technical Problem

The present invention has been made to solve the above-described problems, and aims to provide a sheet form heat-dissipating member that exhibits preferable thermal conductivity even under heat compression at approximately 150° C. and that has excellent heat dissipation performance.

### Solution to Problem

To solve the above problem, the present invention provides a sheet form heat-dissipating member to be provided between a heat-generating electronic component and a heat-dissipating component, wherein
the sheet form member is non-flowable at room temperature and becomes flowable due to heat generated from the heat-generating electronic component during operation of the heat-generating electronic component or due to heat actively applied during arrangement of the heat-generating electronic component, whereby an interface between the heat-generating electronic component and the heat-dissipating component is filled with the sheet form member with substantially no voids,
the sheet form heat-dissipating member containing a heat-softening thermally conductive composition comprising:
(A) 100 parts by mass of a silicone resin having a melting point of 40 to 110° C.;
(B) 500 to 1,850 parts by mass of silver powder; and
(C) 1.0 to 20 parts by mass of an organohydrogenpolysiloxane,
the component (A) includes an R¹SiO_{3/2} unit (wherein R¹ is a group selected from alkyl groups having 1 to 10 carbon atoms and aryl groups having 6 to 10 carbon atoms) and an R²SiO_{2/2} unit (wherein R² is a group selected from alkyl groups having 1 to 10 carbon atoms, alkenyl groups having 2 to 10 carbon atoms, and aryl groups having 6 to 10 carbon atoms),
the silver powder as the component (B) has an average particle diameter of 0.5 to 10 μm, and the heat-softening thermally conductive composition comprises 30 to 60 vol % of the silver powder as the component (B), and
the organohydrogenpolysiloxane as the component (C) includes an organohydrogenpolysiloxane having two or more hydrosilyl groups in one molecule.

The sheet form heat-dissipating member of the present invention has favorable handleability and can be easily mounted on heat-dissipating component. In addition, by thermal press bonding, the sheet softens, follows the shape and unevenness of the heat-dissipating member, and becomes thinner, and the contact thermal resistance and the thermal resistance of the sheet itself can be reduced. Furthermore, even when heat compressed at approximately 150° C., the sheet can achieve high thermal conductivity, and its thermal resistance can be reduced.

Therefore, the sheet form heat-dissipating member of the present invention is highly effective as a heat-conducting member that is interposed between a heat-generating electronic component (a heat-generating device) and the heat-dissipating component, and which transmits heat generated from the heat-generating electronic component to the heat-dissipating component.

The heat-softening thermally conductive composition preferably further comprises an auxiliary inorganic filler other than the silver powder as the component (B), and the auxiliary inorganic filler is selected from the group consisting of aluminum powder, copper powder, gold powder, zinc oxide powder, aluminum nitride powder, aluminum oxide powder, and silicon dioxide powder.

By further containing an auxiliary inorganic filler other than the silver powder, further improvement in thermal conductivity can be achieved.

The heat-softening thermally conductive composition can further contain, as (D) a plasticizer, a linear organopolysiloxane having one or more aryl groups having 6 to 20 carbon atoms in one molecule.

By further including the plasticizer further improves the handleability of the sheet form heat-dissipating member and further reduces the thickness after thermal bonding.

It is preferable that the heat-softening thermally conductive composition is free from a metal catalyst that promotes a hydrosilylation reaction.

By not including a metal catalyst that promotes the hydrosilylation reaction, it is possible to suppress the consumption of the hydrosilyl groups of the component (C) in the hydrosilylation reaction, and as a result, it is possible to more reliably achieve the desired thermal conductivity.

### Advantageous Effects of Invention

As described above, according to the sheet form heat-dissipating member of the present invention, even when heat-compressed at approximately 150° C., preferable thermal conductivity can be exhibited, and excellent heat dissipation performance can be obtained.

### BRIEF DESCRIPTION OF DRAWING

FIG. 1 is a schematic cross-sectional view showing one example of the sheet form heat-dissipating member of the present invention.

### DESCRIPTION OF EMBODIMENTS

As described above, there has been a demand for the development of a sheet form heat-dissipating member that exhibits preferable thermal conductivity and provides excellent heat dissipation performance even when subjected to heat compression at approximately 150° C.

The present inventors have conducted extensive studies to achieve the above-described object, and as a result, have found that a sheet form heat-dissipating member capable of reducing thermal resistance even when subjected to heat compression at approximately 150° C. can be obtained by incorporating an organohydrogenpolysiloxane, which serves as a sintering-promoting component for silver powder, into a thermally softening silicone resin and silver powder, and by setting the average particle diameter and content of the silver powder, as well as the content of the organohydrogenpolysiloxane, within specific ranges, and thus, the present invention has been accomplished.

In other words, the present invention is a sheet form heat-dissipating member to be provided between a heat-generating electronic component and a heat-dissipating component, wherein
the sheet form member is non-flowable at room temperature and becomes flowable due to heat generated from the heat-generating electronic component during operation of the heat-generating electronic component or due to heat actively applied during arrangement of the heat-generating electronic component, whereby an interface between the heat-generating electronic component and the heat-dissipating component is filled with the sheet form member with substantially no voids,
the sheet form heat-dissipating member containing a heat-softening thermally conductive composition comprising:
(A) 100 parts by mass of a silicone resin having a melting point of 40 to 110° C.;
(B) 500 to 1,850 parts by mass of silver powder; and
(C) 1.0 to 20 parts by mass of an organohydrogenpolysiloxane,
the component (A) includes an R¹SiO_{3/2} unit (wherein R¹ is a group selected from alkyl groups having 1 to 10 carbon atoms and aryl groups having 6 to 10 carbon atoms) and an R²₂SiO_{2/2} unit (wherein R² is a group selected from alkyl groups having 1 to 10 carbon atoms, alkenyl groups having 2 to 10 carbon atoms, and aryl groups having 6 to 10 carbon atoms),
the silver powder as the component (B) has an average particle diameter of 0.5 to 10 Um, and the heat-softening thermally conductive composition comprises 30 to 60 vol % of the silver powder as the component (B), and
the organohydrogenpolysiloxane as the component (C) includes an organohydrogenpolysiloxane having two or more hydrosilyl groups in one molecule.

Hereinafter, the present invention will be described in detail; however, the present invention is not limited thereto.

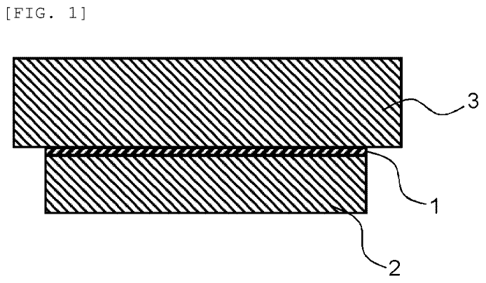

As schematically illustrated in FIG. 1, a sheet form heat-dissipating member 1 according to the present invention is the sheet form heat-dissipating member provided between a heat-generating electronic component 2 and a heat-dissipating component 3. The heat-generating electronic component 2 refers to an electronic component that may reach a temperature above room temperature during operation. The sheet form member is non-flowable at room temperature and becomes flowable due to heat generated from the heat-generating electronic component 2 during operation of the heat-generating electronic component 2 or due to heat actively applied during arrangement of the heat-generating electronic component 2, whereby an interface between the heat-generating electronic component 2 and the heat-dissipating component 3 is filled with the sheet form member with substantially no voids. As used herein, the expression “filled with substantially no voids” refers to a state in which no voids or no unfilled regions can be observed under microscopic observation.

In addition, the sheet form heat-dissipating member according to the present invention comprises heat-softening thermally conductive composition, the heat-softening thermally conductive composition comprising the following components (A) to (C):
(A) 100 parts by mass of a silicone resin having a melting point of 40 to 110° C.;
(B) 500 to 1,850 parts by mass of silver powder; and
(C) 1.0 to 20 parts by mass of an organohydrogenpolysiloxane.

The sheet form heat-dissipating member 1 of the present invention exhibits good adhesion to both the heat-generating electronic component 2 and the heat-dissipating component 3, and can achieve a substantially reduced thickness, thereby enabling a significant reduction in thermal resistance.

More specifically, the sheet form heat-dissipating member 1 of the present invention has favorable handleability and can be easily mounted on heat-dissipating component 3. In addition, by thermal press bonding, the sheet softens, follows the shape and unevenness of the heat-dissipating component 3, and becomes thinner, and the contact thermal resistance and the thermal resistance of the sheet itself can be reduced. Furthermore, even when heat compressed at approximately 150° C., the sheet can achieve high thermal conductivity, and its thermal resistance can be reduced.

Each component will now be described in detail.

### (A) Silicone Resin

A component (A) is a silicone resin having a melting point of 40 to 110° C., and forms the matrix of the sheet form heat-dissipating member according to the present invention. The component (A) is a silicone resin such that the heat-dissipating member of the present invention is substantially solid (non-flowable) at room temperature (e.g., 25° C.); but undergoes thermal softening, viscosity reduction, or melting to become flowable at a temperature below the maximum temperature reached due to heat generated from the heat-generating electronic component, specifically in a temperature range of approximately 40 to 110° C., and particularly 60 to 100° C., or undergoes thermal softening, viscosity reduction, or melting to become flowable due to heat actively applied during arrangement of the heat-generating electronic component (specifically in a temperature range of for example, approximately 40 to 110° C., and particularly approximately 60 to 100° C.). The component (A) serves as a factor that causes thermal softening of the sheet form heat-dissipating member of the present invention, and also functions as a binder that imparts processability and workability to the silver powder serving as a filler that provides thermal conductivity to the sheet form heat-dissipating member.

It should be noted that in the present invention, the term “room temperature” refers to a temperature range of 10° C. or more and less than 40° C.

Here, the temperature at which thermal softening, viscosity reduction, or melting occurs refers to the temperature of the heat-dissipating member, and the melting point of the silicone resin itself is from 40 to 110° C., preferably from 50 to 90° C. When the melting point of the silicone resin itself is 40° C. or more, it is possible to suppress the development of adhesiveness in the sheet form heat-dissipating member and to maintain excellent handleability. Further, when the melting point of the silicone resin itself is 110° C. or less, it is possible to sufficiently suppress the progression of silver sintering concurrently with the thermal softening of the sheet form heat-dissipating member, thereby allowing the sheet form heat-dissipating member to be sufficiently thinned even by heat compression at approximately 150° C.

It should be noted that the melting point of the silicone resin in the present invention is a value measured by a visual method described in JIS K0064:1992, and in the case of a silicone resin that does not exhibit a clear melting point, the melting range thereof is treated as the melting point.

The component (A) is characterized by containing an R¹SiO_{3/2} unit (hereinafter referred to as “T unit”) and an R 2SiO_{2/2} unit (hereinafter referred to as “D unit”). The component (A) may further contain a SiO_{4/2} unit (hereinafter referred to as “Q unit”) and an R²₃SiO_{1/2} unit (hereinafter referred to as “M unit”), in addition to the above-described T unit and D unit.

Here, R¹ is a group selected from alkyl groups having 1 to 10 carbon atoms and aryl groups having 6 to 10 carbon atoms. Specific examples of R¹ include alkyl groups such as a methyl group, an ethyl group, a propyl group, an isopropyl group, a butyl group, an isobutyl group, a tert-butyl group, a pentyl group, a neopentyl group, a hexyl group, a cyclohexyl group, an octyl group, a nonyl group, and a decyl group, and aryl groups such as a phenyl group, a tolyl group, a xylyl group, and a naphthyl group. Among them, a methyl group or a phenyl group is preferred, with a methyl group and a phenyl group being particularly desirable from the standpoint of flame retardancy.

Here, R² is a group selected from alkyl groups and aryl groups as defined for R¹, and alkenyl groups having 2 to 10 carbon atoms. Specific examples of Re include, in addition to the specific examples of R¹, alkenyl groups such as a vinyl group, an allyl group, a propenyl group, an isopropenyl group, a butenyl group, a hexenyl group, a cyclohexenyl group, and an octenyl group, and among them, a vinyl group or an allyl group is preferable from the perspective of flame retardancy.

The silicone resin as the component (A) will be described in more detail. The silicone resin used in the present invention needs to contain T unit and D unit to be non-flowable at room temperature. Representative examples of such silicone resins include silicone resins composed of a combination of T unit, D unit, and M unit.

By introducing T unit, the toughness can be improved, and the brittleness in the solid state at room temperature can be improved, thereby preventing breakage or the like during handling. Also, by introducing D unit, the toughness at room temperature can be improved. For example, a preferred structure of the silicone resin includes a silicone resin composed of a combination of M unit/T unit/D unit. In addition, in the silicone resin composed of the combination of M unit/T unit/D unit, the ratio of T unit to D unit is preferably from 10:90 to 90:10, and more preferably from 20:80 to 80:20.

Specific examples of the component (A) include silicone resins having a specific composition of a difunctional structural unit (D unit) and a trifunctional structural unit (T unit) as follows. It should be noted that the siloxane units listed below may be bonded in a block or random manner:

DₘT^{φ}ₚD^{Vi}ₙ
wherein D represents a dimethylsiloxy unit (i.e., (CH₃)₂SiO_{2/2}), T^{φ} represents a phenylsiloxy unit (i.e., (C₆H₅)SiO_{3/2}), D^{Vi} represents a methylvinylsiloxy unit (i.e., (CH₃)(CH₂═CH)SiO_{2/2}), and (m+n)/p (molar ratio) is from 0.25 to 4.0, and (m+n)/m (molar ratio) is from 1.0 to 4.0.

Furthermore, for example, silicone resins having a specific composition of a monofunctional structural unit (M unit), a difunctional structural unit (D unit), and a trifunctional structural unit (T unit) can be exemplified:

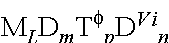

wherein M represents a trimethylsiloxy unit (i.e., (CH₃)₃SiO_{1/2}), D, T^{φ}, and D^{Vi} are as described above, and (m+n)/p (molar ratio) is from 0.25 to 4.0, (m+n)/m (molar ratio) is from 1.0 to 4.0, and L/(m+n) (molar ratio) is from 0.001 to 0.1.

### Method for Measuring Ratios of M Unit, D Unit, T Unit, and Q Unit

In the present invention, the ratios of the monofunctional R¹₃SiO_{1/2} unit (M unit), difunctional R²₂SiO_{2/2} unit (D unit), trifunctional R¹SiO_{3/2} unit (T unit), and tetrafunctional SiO_{4/2} unit (Q unit) in the three-dimensional network (resin-like) structure of the organopolysiloxane resin are values obtained from ²⁹Si-NMR.

The method for preparing the sample for ²⁹Si-NMR is not particularly limited; for example, the measurement can be performed by using one obtained by dissolving 1 part by mass of the organopolysiloxane resin in 3 parts by mass of deuterochloroform. Furthermore, the average degree of polymerization of the silicone resin, that is, the total amount of the M unit, D unit, T unit, and Q unit, is preferably 30 to 300, and more preferably 50 to 150.

It should be noted that in the present invention, the average degree of polymerization is a value obtained as the number average degree of polymerization (number-average molecular weight) in terms of polystyrene by GPC (gel permeation chromatography) analysis using toluene as a developing solvent.

### (B) Silver Powder

A component (B) is silver powder that serves as a thermally conductive filler. The method for producing the silver powder is not particularly limited, and examples thereof include an electrolytic method, a heat treatment method, an atomization method, and a reduction method. The shape of the silver powder is also not particularly limited, and examples thereof include flake form, spherical form, granular form, amorphous, needle-like form, and the like.

The silver powder as the component (B) has an average particle diameter of 0.5 to 10 μm. Preferably, the silver powder has an average particle diameter of 1 to 8 μm, and more preferably 2 to 6 μm. As the thermally conductive filler, silver powder may be used alone, or in combination with another type of filler other than the silver powder. The filler other than the silver powder will be described later. Two or more kinds of particles having different average particle diameters may also be used. The above average particle diameter is a value obtained as a cumulative volume average diameter D50 (or median diameter) and the like measured by laser diffraction particle size distribution measurement. Specifically, it is the value of the cumulative 50% particle diameter (D50) on a volume basis, as measured by a particle size distribution measuring apparatus MT3000II manufactured by MicrotracBEL Corp.

The component (B) may be subjected to various surface treatments, which are known in the art. Specifically, treatments with coupling agent such as silane-based and titanate-based agents and plasma treatment are examples.

The blending amount of the component (B) is from 500 to 1,850 parts by mass relative to 100 parts by mass of the component (A), and preferably, the amount is from 800 to 1,700 parts by mass, and more preferably, from 1,000 to 1,500 parts by mass. If the blending amount of the component (B) is too high, the sheet becomes brittle, and workability is reduced. On the other hand, if the blending amount is too low, the desired thermal conductivity cannot be achieved.

The proportion of the silver powder as the component (B) in the heat-softening thermally conductive composition is from 30 to 60 volt. In the same manner as described above, if the proportion of the component (B) is too high, the sheet becomes brittle, and workability is reduced. On the other hand, if the proportion is too low, the desired thermal conductivity cannot be achieved.

### (C) Organohydrogenpolysiloxane

An organohydrogenpolysiloxane as a component (C) acts as a sintering promoter to react with the component (B) so as to accelerate the sintering of the silver powder. Therefore, it is incorporated for a purpose different from that of a crosslinking agent in a conventional addition-curable type organopolysiloxane composition.

The component (C) includes an organohydrogenpolysiloxane having two or more (e.g., from 2 to 50) hydrosilyl groups in one molecule. Preferably, the organohydrogenpolysiloxane has at least one aryl group having 6 to 10 carbon atoms in one molecule. Specific examples of the component (C) include those represented by the following formula.

[R⁴ᵣHSiO_{(3-r)/2}]ᵥ[R³ₛSiO_{(4-s)/2}]_{w}[R⁴ₜSiO_{(4-t)/2}]ₓ

Here, R³ represents an aryl group having 6 to 10 carbon atoms, and specific examples thereof include a phenyl group, a tolyl group, a xylyl group, a naphthyl group, and the like, Among them, a phenyl group is preferred.

Here, R⁴ represents an alkyl group having 1 to 10 carbon atoms, and specific examples of R⁴ include, for example, alkyl groups such as a methyl group, an ethyl group, a propyl group, an isopropyl group, a butyl group, an isobutyl group, a tert-butyl group, a pentyl group, a neopentyl group, a hexyl group, a cyclohexyl group, an octyl group, a nonyl group, and a decyl group. Among them, the methyl group or the ethyl group are preferable.

r is from 0 to 2, and s and t are each 2 or 3.

Furthermore, v is a positive number equal to or greater than 0, preferably from 0.05 to 0.5, and more preferably from 0.1 to 0.4. w is a positive number equal to or greater than 0, preferably from 0.05 to 0.5, more preferably from 0.1 to 0.4. In particular, when v and w are within the above-mentioned ranges, excellent compatibility with the component (A) is exhibited, the reaction with the component (B) proceeds sufficiently, and the handleability and thermal conductivity of the sheet form heat-dissipating member can be further improved. x is a positive number equal to or greater than 0, and preferably from 0 to 0.8. However, the above v, w and x satisfy the relation v+w+x=1.

The hydrosilyl group of the component (C) may be located at the terminal of the molecular chain or at an intermediate position of the molecular chain, or may be located at both positions. The molecular structure of the component (C) may be linear, cyclic, or branched. It is preferable that the average degree of polymerization of the component (C) is from 4 to 200, more preferably from 4 to 120, and still more preferably from 4 to 60.

As the component (C), one type of organohydrogenpolysiloxane may be used alone, or two or more types of organohydrogenpolysiloxanes may be used in combination.

Specific examples of the component (C) include organohydrogenpolysiloxanes having the following structure.

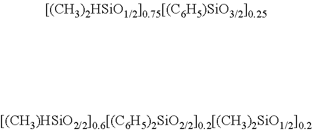

The blending amount of the component (C) is from 1.0 to 20 parts by mass, preferably from 2 to 15 parts by mass, and more preferably from 3 to 10 parts by mass, with respect to 100 parts by mass of the component (A). If the blending amount of the component (C) is too high, the silver powder in the sheet aggregates over time when the sheet is stored at 40° C., resulting in hardening of the sheet, which makes it difficult to soften the sheet even by thermal press bonding. On the other hand, if the blending amount of the component (C) is too low, the sintering-promoting effect of the silver powder cannot be sufficiently obtained, and the desired thermal conductivity cannot be achieved.

The component (C) is intended to obtain a sintering-promoting effect of the silver powder, and if the consumption of hydrosilyl groups of the component (C) in the hydrosilylation reaction can be suppressed, the desired thermal conductivity can be reliably achieved. Accordingly, it is preferable that a metal catalyst for promoting the hydrosilylation reaction is not contained.

### (D) Plasticizer

To improve the handleability of the sheet and to reduce the thickness after thermal press bonding, a component (D) as a plasticizer may be mixed into the above heat-softening thermally conductive composition. The plasticizer is preferably a linear organopolysiloxane having one or more (e.g., 1 to 40) aryl groups having 6 to 10 carbon atoms in one molecule, in view of compatibility with the component (A).

Specific examples of the component (D) include those represented by the following formula,

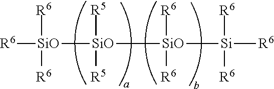

Wherein R⁵ is an aryl group having 6 to 10 carbon atoms or an aralkyl group having 7 to 10 carbon atoms, and specific examples thereof include aryl group such as a phenyl group, a tolyl group, a xylyl group, and a naphthyl group, and aralkyl group, such as a benzyl group. Among them, the phenyl group is preferable.

Also, wherein R⁶ is a monovalent hydrocarbon group selected from an alkyl group having 1 to 10 carbon atoms, preferably 1 to 6 carbon atoms, or an alkenyl group having 2 to 10 carbon atoms, preferably 2 to 4 carbon atoms. Examples of the monovalent hydrocarbon group include alkyl groups such as a methyl group, an ethyl group, a propyl group, an isopropyl group, a butyl group, an isobutyl group, a tert-butyl group, a pentyl group, a neopentyl group, a hexyl group, a heptyl group, and an octyl group, and cycloalkyl groups such as a cyclopentyl group, a cyclohexyl group, and a cycloheptyl groups, and alkenyl groups such as a vinyl group, an allyl group, a propenyl group, an isopropenyl group, a butenyl group, a hexenyl group, a cyclohexenyl group, and an octenyl group. Among them, the methyl group or the vinyl group is preferable.

The siloxane units enclosed by a and b may be bonded in a block manner or in a random manner. The ratio of each of the siloxane units satisfies 0<a≤1.0 and 0≤b≤0.8, provided that a+b=1.

As the component (D), a single plasticizer may be used alone, or two or more plasticizers may be used in combination.

Examples of the properties of the component (D) include oily and gummy organopolysiloxanes (silicone oils and silicone raw rubbers).

Specific examples of the component (D) include organopolysiloxane having the following structure.

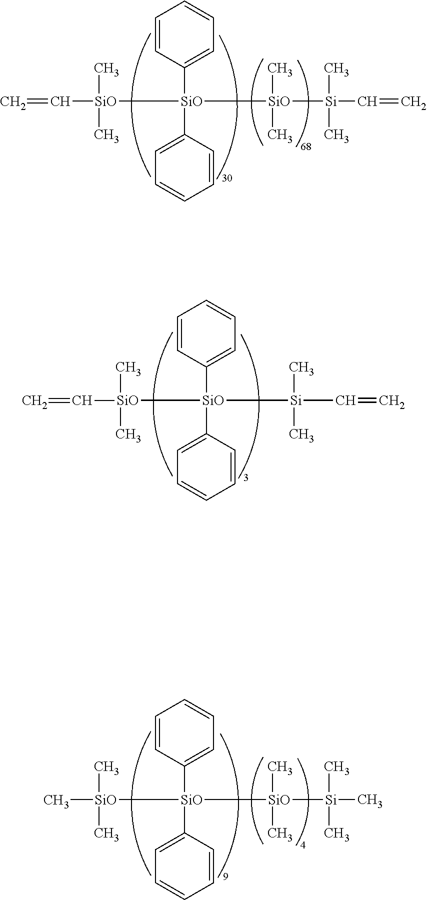

When the component (D) is added to the heat-softening thermally conductive composition constituting the sheet form heat-dissipating member of the present invention, the amount thereof is preferably from 1 to 100 parts by mass, and more preferably from 2 to 20 parts by mass, with respect to 100 parts by mass of the silicone resin as the component (A). When the amount added is within this range, the resulting composition is likely to have improved handleability and is also likely to become thinner after thermal press bonding, thereby making it possible to reduce thermal resistance.

(E) Auxiliary Inorganic Filler Other than Silver Powder

To improve the handleability of the sheet and to further enhance thermal conductivity, an auxiliary inorganic filler as a component (E), which is a thermally conductive powder other than silver powder, may be mixed into the heat-softening thermally conductive composition.

Examples of the component (E) include: metal powders such as aluminum powder, copper powder, gold powder, and the like; and inorganic powders such as zinc oxide powder, aluminum nitride powder, aluminum oxide powder, silicon dioxide powder, and the like.

The component (E) enters the gaps among the component (B) filling the above heat-softening thermally conductive composition, thereby improving the overall filling of the composition with the thermally conductive powder (component (B)). Moreover, the stability of the composition is improved, oil separation during thermal softening can be prevented, and the handleability is improved.

The average particle diameter of the component (E) is preferably from 0.5 to 10 μm, more preferably from 1 to 8 μm, and even more preferably from 2 to 6 μm. When the average particle diameter is 0.5 μm or more, it is possible to suppress the bulk density of the component (B), thereby facilitating high filling of the heat-softening thermally conductive composition with the component (B). When the average particle diameter is 10 μm or less, the component (B) has a greater influence on the thermal conductivity than the component (E), and the contribution of the component (B) to improved thermal conductivity by virtue of sintering becomes significant, thereby allowing the thermal conductivity of the sheet form heat-dissipating member to be enhanced.

As the auxiliary inorganic filler, one kind thereof may be used alone or two or more kinds thereof may be used in combination.

The blending amount of the component (E) is preferably from 1 to 100 parts by mass with respect to 100 parts by mass of the component (A), more preferably from 1 to 70 parts by mass, and still more preferably from 1 to 50 parts by mass. When the blending amount of the component (E) is from 1 to 100 parts by mass, embrittlement of the sheet form heat-dissipating member can be prevented, and sufficient workability can be achieved.

When the component (E) is blended, the proportion of the total amount of the component (B) and the component (E) in the heat-softening thermally conductive composition is preferably from 30 to 60 volt.

### Production Method

The heat-softening thermally conductive composition used in the sheet form heat-dissipating member of the present invention can be easily produced by blending and kneading the above components using rubber kneading machines such as a kneader, a gate mixer, a planetary mixer, and the like.

The sheet form heat-dissipating member of the present invention can be produced by molding the heat-softening thermally conductive composition into a sheet form. Herein, the term “sheet form” is used to encompass film-like and tape-like forms. Examples of methods for molding into a sheet form include a method in which the kneaded composition is molded by extrusion molding, calender molding, roll molding, or press molding, and a method in which the composition dissolved in a solvent is coated. The thickness of the sheet form heat-dissipating member produced in this manner is preferably from 20 to 200 μm, more preferably from 20 to 100 μm, and particularly preferably from 30 to 80 μm. When the thickness is within this range, handleability and heat dissipation performance can be favorably maintained.

### EXAMPLES

Hereinafter, the present invention will be described in more detail with reference to Examples and Comparative Examples; however, the present invention is not limited thereto.

The components (A) to (E) constituting the thermally conductive adhesive layer used in the Examples and Comparative Examples below are as follows. It is to be noted that, in the following description, M refers to a trimethylsiloxy unit (i.e., (CH₃)₃SiO_{1/2}); D refers to a dimethylsiloxy unit (i.e., (CH₃)₂SiO_{2/2}), D^{φ} refers to a diphenylsiloxy unit (i.e., (C₆H₅)₂SiO_{2/2}), D^{Vi} refers to a methylvinylsiloxy unit (i.e., (CH₃)(CH₂═CH)SiO_{2/2}), and T^{φ} refers to a phenylsiloxy unit (i.e., (C₆H₅)SiO_{3/2}).

### Component (A):

(A-1) A silicone resin represented by the following formula and having a melting point of 50 to 70° C. (average degree of polymerization: 100)

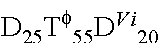

(A-2) A silicone resin represented by the following formula and having a melting point of 80 to 100° C. (average degree of polymerization: 100)

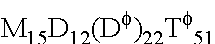

(A-3) A silicone resin represented by the following formula and having a melting point of 120 to 140° C. (average degree of polymerization: 116) (for comparison)

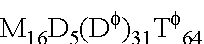

(A-4) An acrylic-modified silicone represented by the following formula and having a melting point of 27 to 32° C. (trade name: KP-561, produced by Shin-Etsu Chemical Co., Ltd.) (for comparison)

### Component (B):

(B-1) A flake-like silver filler having a volume average particle diameter of 3 μm
(B-2) A spherical silver filler having a volume average particle diameter of 4 μm
(B-3) A spherical silver filler having a volume average particle diameter of 20 Mm (for comparison)

### Component (C):

(C-1) An organohydrogenpolysiloxane represented by the following formula (average degree of polymerization: 10)

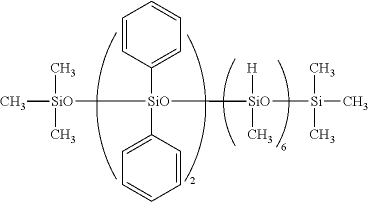

(C-2) An organohydrogenpolysiloxane represented by the following formula (average degree of polymerization: 32)

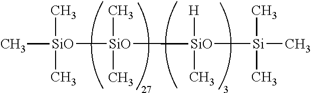

Component (D): An organopolysiloxane represented by the following formula and serving as a plasticizer

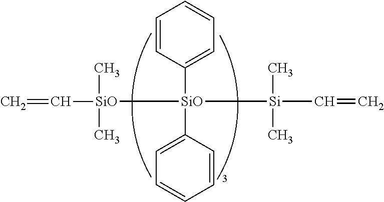

Component (E): A spherical aluminum filler having volume average particle diameter of 2 μm

The above components (A), (B), (D), and (E) were charged into a planetary mixer in any of the blending ratios shown in the following Tables 1 and 2, and mixed for 60 minutes. Subsequently, an appropriate amount of xylene solvent was added in accordance with the coating conditions, and component (C) was added in any of the blending ratios shown in the following Tables 1 and 2, followed by uniform mixing to obtain a uniform coating liquid of a heat-softening thermally conductive composition. The resulting coating liquid was applied onto a separate film serving as a base material so that the thickness of the sheet form heat-dissipating member after drying would be 200 μm, and then the coating film was dried to produce respective sheet form heat-dissipating members (heat-softening thermally conductive sheets). Another separate film was disposed on the produced sheet form heat-dissipating member, such that the sheet form heat-dissipating member was sandwiched between two separate films.

### [Evaluation Method]

(1) Handleability: The handleability was evaluated by determining whether the sheet form heat-dissipating member of each Example exhibited the desired adhesion when applied to a heat-dissipating component (aluminum heat sink).

Specifically, one separator film was peeled off, and the sheet form heat-dissipating member was adhered to the aluminum heat sink, and thereafter, another separator film was peeled off, and it was evaluated whether the sheet form heat-dissipating member remained fixed to the heat sink without displacement. A result in which the member was fixed without displacement was marked as “Good”, and a result in which displacement occurred was marked as “Poor”, as shown in the tables. It is to be note that the evaluations described below were not performed on the samples that were rated “Poor” in handleability.
(2) Thermal Conductivity: The separator films on both sides of the sheet form heat-dissipating member were peeled off, and the member was sandwiched between aluminum plates, was uniformity subjected to press bonding, and then the sample was subjected to heat curing under the conditions of 150° C./20 psi×1 hr using a drying apparatus, and thereafter the thermal diffusivity was measured by a laser flash method. The effective thermal conductivity was calculated from the relationship among thermal diffusivity, density, and specific heat capacity, according to following equation:

$$Thermal conductivity ( W / m \cdot K ) = Thermal diffusivity ( {mm}^{2} / s ) \times Density ( g / {cm}^{3} ) \times Specific heat capacity ( J / g \cdot K )$$

(3) Thermal Resistance: The effective thermal resistance was calculated from the thermal conductivity obtained by the laser flash method and the thickness of the sample, using the following equation:

$$Thermal resistance ( {mm}^{2} \cdot K / W ) = thickness ( μ m ) \div thermal conductivity ( W / m \cdot K )$$

(4) Storage Stability: A sheet form heat-dissipating member with separator films on both sides was left to stand in a drying apparatus at 40° C. for two weeks, and thereafter the sheet was taken out of the drying apparatus and allowed to cool to 25° C. Subsequently, the thermal conductivity of the cooled sheet was measured. The sample was evaluated as “Good” when the thermal conductivity after the storage test was 80% or more relative to the thermal conductivity before the storage test (before placing in the drying apparatus at 40° C.), and as “Poor” when it was less than 80%, as shown in the tables.

Hereinafter, Examples and Comparative Examples and the corresponding heat-softening thermally conductive compositions used in each example are summarized. The compositions (A) to (M) described below are heat-softening thermally conductive compositions obtained with the blending ratios described in Table 1 and Table 2.

### Example 1

By using Composition (A), coating was performed on a separator film to obtain a sheet form heat-dissipating member (heat-softening thermally conductive sheet) of Example 1.

### Example 2

By using Composition (B), coating was performed on a separator film to obtain a sheet form heat-dissipating member (heat-softening thermally conductive sheet) of Example 2.

### Example 3

By using Composition (C), coating was performed on a separator film to obtain a sheet form heat-dissipating member (heat-softening thermally conductive sheet) of Example 3 was obtained.

### Example 4

By using Composition (D), coating was performed on a separator film to obtain a sheet form heat-dissipating member (heat-softening thermally conductive sheet) of Example 4.

### Example 5

By using Composition (E), coating was performed on a separator film to obtain a sheet form heat-dissipating member (heat-softening thermally conductive sheet) of Example 5.

### Example 6

By using Composition (F), coating was performed on a separator film to obtain a sheet form heat-dissipating member (heat-softening thermally conductive sheet) of Example 6.

### Comparative Example 1

By using Composition (G), coating was performed on a separator film to obtain a sheet form heat-dissipating member (heat-softening thermally conductive sheet) of Comparative Example 1. The resulting sheet had low thermal conductivity and high thermal resistance.

### Comparative Example 2

By using Composition (H), coating was performed on a separator film to obtain a sheet form heat-dissipating member (heat-softening thermally conductive sheet) of Comparative Example 2. The initial thermal conductivity of the resulting sheet was as high as 25 W/mk; however after storage it was 5 W/mk, indicating a significant decrease in thermal conductivity over time.

### Comparative Example 3

By using Composition (I), coating was performed on a separator film to obtain a sheet form heat-dissipating member (heat-softening thermally conductive sheet) of Comparative Example 3, The sheet of Comparative Example 3 had high adhesiveness and the separator film on one side could not be peeled off.

### Comparative Example 4

By using Composition (J), coating was performed on a separator film to obtain a sheet form heat-dissipating member (heat-softening thermally conductive sheet) of Comparative Example 4. The sheet of Comparative Example 4 exhibited no adhesion and could not be attached to the heat sink.

### Comparative Example 5

By using Composition (K), coating was performed on a separator film to obtain a sheet form heat-dissipating member (heat-softening thermally conductive sheet) of Comparative Example 5. The sheet of Comparative Example 5 had a low filling with the silver powder as the component (B), and sufficient thermal conductivity was not obtained.

### Comparative Example 6

By using Composition (L), coating was performed on a separator film to obtain a sheet form heat-dissipating member (heat-softening thermally conductive sheet) of Comparative Example 6. The sheet of Comparative Example 6 exhibited no adhesion and could not be attached to the heat sink.

### Comparative Example 7

By using Composition (M), coating was performed on a separator film to obtain a sheet form heat-dissipating member (heat-softening thermally conductive sheet) of Comparative Example 7, The adhesion of the sheet was weak, and the sheet could not be fixed to the heat sink.

TABLE 1

| Heat Softening Thermally | | | | | | |
|---|---|---|---|---|---|---|
| Conductive Composition | (A) | (B) | (C) | (D) | (E) | (F) |
| A-1 | 100 | 100 | 85 | 70 | 100 | 100 |
| A-2 | 0 | 0 | 15 | 30 | 0 | 0 |
| Component A (A1 + A2) | 100 | 100 | 100 | 100 | 100 | 100 |
| C-1 | 4.5 | 5.0 | | 4.5 | 5.2 | 5.3 |
| C-2 | | | 18.0 | | | |
| D | | 11.6 | | | 11.6 | 17.7 |
| B-1 | 150 | 325 | 330 | 526 | | 619 |
| B-2 | 835 | 932 | 944 | | 1830 | |
| Component B (B1 + B2) | 985 | 1257 | 1274 | 526 | 1830 | 619 |
| E | | | | | | 70.8 |
| Volume Percentage of | 47.3 | 50.7 | 50.7 | 32.4 | 60.0 | 32.0 |
| Component B in | | | | | | |
| Composition | | | | | | |
| (vol %) | | | | | | |
| Volume Percentage of total | 47.3 | 50.7 | 50.7 | 32.4 | 60.0 | 40.9 |
| of Components B and E in | | | | | | |
| Composition | | | | | | |
| (vol %) | | | | | | |
| Handleability | Good | Good | Good | Good | Good | Good |
| Thickness after Thermal | 50 | 62 | 70 | 66.5 | 20 | 59 |
| Press Bonding (μm) | | | | | | |
| Thermal Conductivity after | 18 | 23 | 24 | 13 | 7 | 14 |
| Thermal Press Bonding | | | | | | |
| (W/mk) | | | | | | |
| Thermal Resistance after | 2.8 | 2.7 | 2.9 | 5.1 | 2.9 | 4.2 |
| Thermal Press Bonding | | | | | | |
| (mm² · K/W) | | | | | | |
| Storage Stability | Good | Good | Good | Good | Good | Good |

TABLE 2

| Heat Softening Thermally | | | | | | | |
|---|---|---|---|---|---|---|---|
| Conductive Composition | (G) | (H) | (I) | (J) | (K) | (L) | (M) |
| A-1 | 100 | 100 | | | 100 | 70 | 100 |
| A-2 | | | | | | 30 | |
| A-3 | | | | 100 | | | |
| A-4 | | | 100 | | | | |
| Component A | 100 | 100 | 100 | 100 | 100 | 100 | 100 |
| (A1 + A2 + A3 + A4) | | | | | | | |
| C-1 | 0.5 | 21.0 | 4.5 | 4.5 | 4.5 | 4.5 | 0.5 |
| D | 15.6 | | | | | | 15.6 |
| B-1 | 330 | 300 | 150 | 150 | 350 | 400 | 325 |
| B-2 | 920 | 1010 | 835 | 835 | | 1500 | |
| B-3 | | | | | | | 932 |
| Component B (B1 + B2 + B3) | 1250 | 1310 | 985 | 985 | 350 | 1900 | 1257 |
| Volume Percentage of | 50.6 | 50.8 | 47.3 | 47.3 | 24.0 | 63.4 | 50.7 |
| Component B in | | | | | | | |
| Composition | | | | | | | |
| (vol %) | | | | | | | |
| Handleability | Good | Good | Poor | Poor | Good | Poor | Poor |
| Thickness after Thermal | 46 | 50 | — | — | 40 | — | — |
| Press Bonding (μm) | | | | | | | |
| Thermal Conductivity after | 2 | 25 | — | — | 4 | — | — |
| Thermal Press Bonding | | | | | | | |
| (W/mk) | | | | | | | |
| Thermal Resistance after | 23 | 2 | — | — | 10 | — | — |
| Thermal Press Bonding | | | | | | | |
| (mm² · K/W) | | | | | | | |
| Storage Stability | Good | Poor | — | — | Good | — | — |

From the above results, it was found that each of the sheet form heat-dissipating members of Example 1 to 6, which are examples of the present invention, exhibited favorable handleability and was able to be easily mounted on heat-dissipating members. Furthermore, the sheet form heat-dissipating member of Example 1 to 6 softened upon heat compression at approximately 150° C., followed the shape and unevenness of the heat-dissipating member, and became thinner, and therefore the thermal resistance of the sheet itself was able to be reduced. In addition, by thermal press bonding, the sheet achieved high thermal conductivity, thereby reducing its thermal resistance.

On the other hand, it is found that the sheet form heat-dissipating members of Comparative Examples 1 to 7 exhibited issues such as poor handleability or storage stability, or high thermal resistance.

The present description includes the following embodiments:
[1] A sheet form heat-dissipating member to be provided between a heat-generating electronic component and a heat-dissipating component, wherein the sheet form member is non-flowable at room temperature and becomes flowable due to heat generated from the heat-generating electronic component during operation of the heat-generating electronic component or due to heat actively applied during arrangement of the heat-generating electronic component, whereby an interface between the heat-generating electronic component and the heat-dissipating component is filled with the sheet form member with substantially no voids, the sheet form heat-dissipating member containing a heat-softening thermally conductive composition comprising: (A) 100 parts by mass of a silicone resin having a melting point of 40 to 110° C.; (B) 500 to 1,850 parts by mass of silver powder; and (C) 1.0 to 20 parts by mass of an organohydrogenpolysiloxane, the component (A) includes an R¹SiO_{3/2} unit (wherein R¹ is a group selected from alkyl groups having 1 to 10 carbon atoms and aryl groups having 6 to 10 carbon atoms) and an R¹SiO_{2/2} unit (wherein R² is a group selected from alkyl groups having 1 to 10 carbon atoms, alkenyl groups having 2 to 10 carbon atoms, and aryl groups having 6 to 10 carbon atoms), the silver powder as the component (B) has an average particle diameter of 0.5 to 10 μm, and the heat softening thermally conductive composition comprises 30 to 60 volt of the silver powder as the component (B), and the organohydrogenpolysiloxane as the component (C) includes an organohydrogenpolysiloxane having two or more hydrosilyl groups in one molecule.
[2] The sheet form heat-dissipating member according to [1], wherein the heat-softening thermally conductive composition further comprises an auxiliary inorganic filler in addition to the silver powder as the component (B), and the auxiliary inorganic filler is selected from the group consisting of aluminum powder, copper powder, gold powder, zinc oxide powder, aluminum nitride powder, aluminum oxide powder, and silicon dioxide powder.
[3] The sheet form heat-dissipating member according to [1] or [2], wherein the heat-softening thermally conductive composition further contains, as (D) a plasticizer, a linear organopolysiloxane having one or more aryl groups having 6 to 20 carbon atoms in one molecule.
[4] The sheet form heat-dissipating member according to any one of [1] to [3], wherein the heat-softening thermally conductive composition is free from a metal catalyst that promotes a hydrosilylation reaction.

It should be noted that the present invention is not limited to the above-described embodiments. The embodiments are just examples, and any examples that have substantially the same feature and demonstrate the same functions and effects as those in the technical concept disclosed in claims of the present invention are included in the technical scope of the present invention.

1. A sheet form heat-dissipating member to be provided between a heat-generating electronic component and a heat-dissipating component, wherein
the sheet form member is non-flowable at room temperature and becomes flowable due to heat generated from the heat-generating electronic component during operation of the heat-generating electronic component or due to heat actively applied during arrangement of the heat-generating electronic component, whereby an interface between the heat-generating electronic component and the heat-dissipating component is filled with the sheet form member with substantially no voids,
the sheet form heat-dissipating member containing a heat-softening thermally conductive composition comprising:
(A) 100 parts by mass of a silicone resin having a melting point of 40 to 110° C.;
(B) 500 to 1,850 parts by mass of silver powder; and
(C) 1.0 to 20 parts by mass of an organohydrogenpolysiloxane,
the component (A) includes an R¹SiO_{3/2} unit (wherein R¹ is a group selected from alkyl groups having 1 to 10 carbon atoms and aryl groups having 6 to 10 carbon atoms) and an R²₂SiO_{2/2} unit (wherein R² is a group selected from alkyl groups having 1 to 10 carbon atoms, alkenyl groups having 2 to 10 carbon atoms, and aryl groups having 6 to 10 carbon atoms),
the silver powder as the component (B) has an average particle diameter of 0.5 to 10 μm, and the heat softening thermally conductive composition comprises 30 to 60 volt of the silver powder as the component (B), and
the organohydrogenpolysiloxane as the component (C) includes an organohydrogenpolysiloxane having two or more hydrosilyl groups in one molecule.

2. The sheet form heat-dissipating member according to claim 1, wherein the heat-softening thermally conductive composition further comprises an auxiliary inorganic filler in addition to the silver powder as the component (B), and
the auxiliary inorganic filler is selected from the group consisting of aluminum powder, copper powder, gold powder, zinc oxide powder, aluminum nitride powder, aluminum oxide powder, and silicon dioxide powder.

3. The sheet form heat-dissipating member according to claim 1, wherein the heat-softening thermally conductive composition further contains, as (D) a plasticizer, a linear organopolysiloxane having one or more aryl groups having 6 to 20 carbon atoms in one molecule.

4. The sheet form heat-dissipating member according to claim 1, wherein the heat-softening thermally conductive composition is free from a metal catalyst that promotes a hydrosilylation reaction.
